(19) United States
(12) Patent Application Publication
(10) Pub. No.: US 2013/0070542 A1
(43) Pub. Date: Mar. 21, 2013

(54) Replica Circuit and It's Applications

(71) Applicant: Koji Shinbayashi, Hyogo (JP)

(72) Inventor: Koji Shinbayashi, Hyogo (JP)

(73) Assignee: Genusion, Inc., Hyogo (JP)

(21) Appl. No.: 13/421,255

(22) Filed: Mar. 15, 2012

(30) Foreign Application Priority Data
Mar. 18, 2011 (JP) 2011-061513
Apr. 21, 2011 (JP) 2011-095069

(51) Int. Cl. G05F 1/10; G11C 7/00

(52) U.S. Cl. CPC G05F 1/10; G11C 7/00
USPC 365/189.11; 365/189.011; 323/271

(57) ABSTRACT

A replica circuit includes: a first conductivity type first transistor; a first current path including a first conductivity type second transistor and a second conductivity type third transistor; a second current path including a first conductivity type fourth transistor configured so that current equivalent to a current flowing through the first transistor flows through the fourth transistor, and a second conductivity type fifth transistor configured so that current equivalent to a current flowing through the third transistor flows through the fifth transistor, the fourth transistor and the fifth transistor being connected in series; a second conductivity type sixth transistor configured so a current equivalent to a current flowing through the third transistor flows through the sixth transistor; a first control configured to supply a reference voltage to the drain of the first transistor; and a second control configured to supply the reference voltage to the drain of the fourth transistor.

### CROSS REFERENCE TO RELATED APPLICATION

This application claims the benefit of priority from prior Japanese Patent Application Nos. 2011-095069, filed on Apr. 21, 2011, and 2011-061513, filed on Mar. 18, 2011, the entire contents of both of which are incorporated herein by reference.

### FIELD OF THE INVENTION

The present invention relates to a replica circuit, a high-voltage detecting circuit, a high-voltage regulator circuit, and a non-volatile semiconductor memory device. The invention relates particularly to a replica detecting circuit that replicates a reference current by causing a current identical with the reference current and flowing through a certain transistor to flow through another transistor, and to a high-voltage detecting circuit using the replica detecting circuit.

### BACKGROUND OF THE INVENTION

A semiconductor device serving as a non-volatile memory, etc., is provided with a charge pump circuit used for data writing or deletion, which raises a source voltage VCC to generate a voltage VP higher than the source voltage VCC. The charge pump circuit detects an output high voltage, and stops a charge pumping operation when the detected voltage is higher than a given voltage while starts the charge pumping operation when the detected voltage is lower than the given voltage. The charge pump circuit performs negative feedback control in this manner to adjust the output high voltage to a target voltage.

FIG. 8 depicts an example of a replica detecting circuit section making up a high-voltage detecting circuit used for controlling the operation of the charge pump circuit.

A PMOS transistor MP0 and a reference resistance Rref are connected in series between a node of a source voltage VCC and a node of a ground voltage VSS. A differential amplifier AMP0 has a negative input terminal supplied with a reference voltage VREF and a positive input terminal connected to a connection point between the PMOS transistor MP0 and the reference resistance Rref, that is, the drain of the PMOS transistor MP0. The output end of the differential amplifier AMP0 is connected to the gate of the PMOS transistor MP0.

A PMOS transistor MP1 and an NMOS transistor MN0 are connected in series between the node of the source voltage VCC and the node of the ground voltage VSS. The gate of the PMOS transistor MP1 is connected to the gate of the PMOS transistor MP0. The PMOS transistor MP1 and the PMOS transistor MP0 are the same size (gate length and gate width) with each other. The gate of the NMOS transistor MN0 is connected to a connection point between the PMOS transistor MP1 and the NMOS transistor MN0, that is, the drain of the NMOS transistor MN0.

A detection resistance element (having a resistance value equivalent to the resistance value of n reference resistances Rref connected in series, n representing a figure that may not be an integer) and an NMOS transistor MN1 are connected in series between a high-voltage terminal VP and the node of the ground voltage VSS. The gate of the NMOS transistor MN1 is connected to the gate of the NMOS transistor MN0. The NMOS transistor MN1 and the NMOS transistor NM0 are the same size (gate length and gate width) with each other. From a connection point between the detection resistance element and the NMOS transistor MN1, a detection terminal VDIV is lead out.

This circuit operates in the following manner. A reference current Iref flowing through the PMOS transistor MP0 and reference resistance Rref is controlled by negative feedback by the differential amplifier AMP0 so that the relation VREF=Iref×Rref is satisfied. The PMOS transistor MP1 and the PMOS transistor MP0 have the gate common to each other and are the same size with each other. For this reason, a current close to the reference current Iref flows through a current path made up of the PMOS transistor MP1 and the NMOS transistor MN0. The NMOS transistor MN1 and the NMOS transistor MN0 have the gate common to each other and are the same size with each other. For this reason, a current close to the reference current Iref flows through a current path made up of the detection resistance element and the NMOS transistor MN1. In this manner, current replication is carried out. As a result, a voltage at the detection terminal VDIV becomes close to a voltage given by VDIV=VP−n×Iref×Rref=VP−n×VREF. A variation ΔVP at the high-voltage terminal VP is substantially the same as a variation ΔVDIV at the detection terminal VDIV. Hence voltage detection more precise than voltage detection by simple resistance dividing is achieved.

The circuit of FIG. 8, however, poses the following problem. As shown in FIG. 9, a reference current Rref 1 flows through a current path of an Iref converting circuit 50, where the reference current Rref 1 is close to a reference current Rref0 but is not identical therewith. This is because that due to a difference in current/voltage characteristics between the reference resistance Rref and the NMOS transistor MN0 (whose gate and drain are connected in the form of diode connection), the PMOS transistor MP0 and the PMOS transistor MP1 have the same source voltage and gate voltage but different drain voltages. Similarly, a reference current Rref 2 flows through the NMOS transistor MN1, where the reference current Rref 2 is close to the reference current Rref1 flowing through the NMOS transistor MN0 but is not identical with the reference current Rref1. This is because that the NMOS transistor MN0 and the NMOS transistor MN1 have the same source voltage and gate voltage but different drain voltages. Hence the currents Iref0, Iref1, and Iref 2 are different in size from each other, thus not matching completely. This results in an error between the variation ΔVP at the high-voltage terminal VP and the variation ΔVDIV at the detection terminal VDIV. Japanese Patent Application Laid-Open Publication No. 2000-19200 is cited as a prior technical document related to this circuit.

A semiconductor device serving as a non-volatile memory, etc., may be provided with a charge pump circuit that raises a source voltage VCC to generate a voltage VP higher than the source voltage VCC.

FIG. 14(a) is a circuit diagram of a conventional charge pump circuit. NMOS transistors T01, T11, T21, T31, and T41 are connected in series between the node of the source voltage VCC and a node supplied with the raised voltage VP. (While an example of series connection of five transistors is depicted, more than five transistors may be connected in series depending on the value of the raised voltage.)

Each node between the transistors T01 and T11, between the transistors T11 and T21, between the transistors T21 and T31, and between the transistors T31 and T41 is denoted as CPD1, CPD2, CPD3, and CPD4. Each node connected to each of the gates of the transistors T01, T11, T21, T31, and T41 is denoted as CPG0, CPG1, CPG2, CPG3, and CPG4.

Between the node of the source voltage VCC and the node CPG0, an NMOS transistor T02 is connected, whose gate is connected to the node CPD1. Between the node CPD1 and the node CPG1, an NMOS transistor T12 is connected, whose gate is connected to the node CPD2. Between the node CPD2 and the node CPG2, an NMOS transistor T22 is connected, whose gate is connected to the node CPD3. Between the node CPD3 and the node CPG3, an NMOS transistor T32 is connected, whose gate is connected to the node CPD4. Between the node CPD4 and the node CPG4, an NMOS transistor T42 is connected, whose gate is connected to the high-voltage terminal VP.

The node CPG0 is connected to a capacitor C00, whose opposed electrodes are driven by a drive signal GCLK2. The node CPG1 is connected to a capacitor C12, whose opposed electrodes are driven by a drive signal GCLK1. The node CPG2 is connected to a capacitor C22, whose opposed electrodes are driven by the drive signal GCLK2. The node CPG3 is connected to a capacitor C32, whose opposed electrodes are driven by the drive signal GCLK1. The node CPG4 is connected to a capacitor C42, whose opposed electrodes are driven by the drive signal GCLK2.

The node CPD1 is connected to a capacitor C11, whose opposed electrodes are driven by the drive signal DCLK1. The node CPD2 is connected to a capacitor C21, whose opposed electrodes are driven by the drive signal DCLK2. The node CPD3 is connected to a capacitor C31, whose opposed electrodes are driven by the drive signal DCLK1. The node CPD4 is connected to a capacitor C41, whose opposed electrodes are driven by the drive signal DCLK2.

FIG. 14(b) depicts the waveforms of the drive signals DCLK1, DCLK2, GCLK1, and GCLK2 that drive the above conventional charge pump circuit. These waveforms are so shaped that the positive pluses of the drive signal GCLK1 are included in the positive pluses of the drive signal DCLK1 and that the positive pluses of the drive signal GCLK2 are included in the positive pluses of the drive signal DCLK2.

FIG. 15(a) depicts a clock buffer circuit that generates the drive signal DCLK1 of FIG. 14(b), FIG. 15(b) depicts a clock buffer circuit that generates the drive signal GCLK1, FIG. 15(c) depicts a clock buffer circuit that generates the drive signal DCLK2, and FIG. 15(d) depicts a clock buffer circuit that generates the drive signal GCLK2.

The clock buffer circuit of FIG. 15(a), for example, is composed of inverters IN11, IN12, IN13, and IN14 that are connected consecutively. Numerical values in FIG. 15(a) (e.g., 3.2 μm and 1.6 μm for the inverter IN11) represent the gate widths of PMOS transistors and NMOS transistors making up the inverters. (In the case of the inverter IN11, therefore, the gate width of the PMOS transistor is 3.2 μm and the same of the NMOS transistor is 1.6 μm.)

The clock buffer circuit of FIG. 15(b), similar to the clock buffer circuit of FIG. 15(a), is composed of inverters IN15, IN16, IN17, and IN18 that are connected consecutively. The gate widths of transistors making up the inverters of FIG. 15(b), however, are smaller than those of FIG. 15(a). For this reason, the clock buffer circuit of FIG. 15(a) has a drive capability higher than that of the clock buffer circuit of FIG. 15(b).

The clock buffer circuits of FIGS. 15(C) and 15(d) are equivalent to the clock buffer circuits of FIGS. 15(a) and 15(b), respectively. (The clock buffer circuit of FIG. 15(C) is composed of consecutively connected inverters IN21, IN22, IN23, and IN24 and the clock buffer circuit of FIG. 15(d) is composed of consecutively connected inverters IN25, IN26, IN27, and IN28.)

When drive signals are generated using the clock buffer circuits of FIG. 15 and the charge pump circuit of FIG. 14(a) is driven by the generated drive signals, the actual waveforms of the drive signals DCLK1, GCLK1, DLCK2, and GCLK2 turn out be waveforms shown in FIG. 16, which indicate the flagging of the drive signal DCLK1. This happens in the following manner. When the drive signal GCLK1 in its low-level state (low voltage level VSS) changes into a high-level state (high voltage level VCC), the transistor T11 becomes conductive, thus allowing a current to flow from the node CPD1 to the node CPD2. As a result, a current also flows into the capacitor C11. This affects the drive signal DCLK1, causing it to dip. Meanwhile, a current inflow causes the drive signal DCLK2 to rise. In the same manner, when the drive signal GCLK2 in its low-level state (low voltage level VSS) changes into a high-level state (high voltage level VCC), the transistor T21 becomes conductive, thus allowing a current to flow from the node CPD2 to the node CPD3. As a result, a current also flows into the capacitor C21. This affects the drive signal DCLK2, causing it to dip.

Such flagging and rising of the drive signals lead to a decline in the efficiency of the charge pump circuit.

To suppress the flagging and rising of the drive signals DCLK1 and DCLK2 as much as possible, the clock buffer circuits of FIGS. 15(a) and 15(c) need a large drive capacity. In the example of FIG. 15, the gate widths of the transistors of the clock buffer circuits of FIGS. 15(a) and 15(c) are so determined that the clock buffer circuits of FIGS. 15(a) and 15(c) have a drive capacity 8 times that of the clock buffer circuits of FIGS. 15(b) and 15(d).

Giving a large drive capacity to each of the clock buffer circuits that generate the drive signals DCLK1 and DCLK2, however, poses a problem that an instantaneous peak current is generated. FIG. 15 depicts the sum ICC of currents flowing from the node of the source voltage VCC toward the node of the ground voltage VSS in these clock buffer circuits. Because the clock buffer circuit that generates the drive signal DCLK1 has a pull-up drive capacity much larger than that of the clock buffer circuit that generates the drive signal GCLK1, the change of the drive signal DCLK1 from its low-level state to a high-level state (at t3) causes an instantaneous large current to flow through the clock buffer circuit, and the change of the drive signal DCLK2 from its low-level state to a high-level state (at t7) causes an instantaneous large current to flow through the clock buffer circuit.

Because the clock buffer circuit that generates the drive signal DCLK1 has a pull-up drive capacity much larger than that of the clock buffer circuit that generates the drive signal GCLK1, the change of the drive signal DCLK1 from its high-level state to a low-level state (at t6) causes an instantaneous large current to flow through the clock buffer circuit, and the change of the drive signal DCLK2 from its high-level state to a low-level state (at t10) causes an instantaneous large current to flow through the clock buffer circuit.

Such peak currents cause a local drop in the source voltage and a large current change di/dt that act as an inductor element, thus creating a noise source, which is a problem. Japanese Patent Application Laid-Open Publication No. 09-198887 is cited as a prior technical document related to these circuits.

An object of the present invention is to provide a replica circuit capable of accurately replicating a current, a high-voltage detecting circuit capable of accurately detecting a high voltage using the replica circuit, and a high-voltage generating circuit and a non-volatile semiconductor memory device using the high-voltage generating circuit.

Another object of the present invention is to provide a voltage converting circuit that suppresses flagging and rising of a drive signal and that reduces a peak current and to provide a semiconductor memory device having such a voltage converting circuit.

### SUMMARY OF THE INVENTION

In order to solve the above problems, according to one embodiment of the present invention, a replica circuit is provided, which comprises a first conductivity type first transistor; a first current path including a first conductivity type second transistor and a second conductivity type third transistor that are connected in series with each other; a second current path including a first conductivity type fourth transistor so configured that a current equivalent to a current flowing through the first transistor flows through the first conductivity type fourth transistor and a second conductivity type fifth transistor so configured that a current equivalent to a current flowing through the third transistor flows through the second conductivity type fifth transistor, the first conductivity type fourth transistor and the second conductivity type fifth transistor being connected in series with each other; a second conductivity type sixth transistor so configured that a current equivalent to a current flowing through the third transistor flows through the second conductivity type sixth transistor; a first control means that controls a gate voltage of the first transistor so that a drain voltage of the first transistor becomes substantially equal to a reference voltage; and a second control means that controls a gate voltage of the second transistor so that a drain voltage of the fourth transistor becomes substantially equal to the reference voltage.

In this replica circuit, the gate of the first transistor and the gate of the fourth transistor may be connected in common to each other, and the drain and gate of the third transistor, the gate of the fifth transistor, and the gate of the sixth transistor may be connected in common to each other.

In this replica circuit, the first control means may be a first differential amplifier supplied with the reference voltage and a drain voltage of the first transistor and having an output end connected to the gate of the first transistor, and the second control means may be a second differential amplifier supplied with the reference voltage and a drain voltage of the fourth transistor and having an output end connected to the gate of the second transistor.

In order to solve the above problems, according to another embodiment of the present invention, a high-voltage detecting circuit is provided, which comprises a reference current path including a first resistance and a first conductivity type first transistor that are connected in series with each other; a first current path including a first conductivity type second transistor and a second conductivity type third transistor that are connected in series with each other; a second current path including a first conductivity type fourth transistor so configured that a current equivalent to a current flowing through the first transistor flows through the first conductivity type fourth transistor and a second conductivity type fifth transistor so configured that a current equivalent to a current flowing through the third transistor flows through the second conductivity type fifth transistor, the first conductivity type fourth transistor and the second conductivity type fifth transistor being connected in series with each other; a third current path including a second resistance and a second conductivity type sixth transistor so configured that a current equivalent to a current flowing through the third transistor flows through the second conductivity type sixth transistor, the second resistance and the second conductivity type sixth transistor being connected in series with each other between a high-voltage terminal and a reference voltage terminal; a first control means that controls a gate voltage of the first transistor so that a drain voltage of the first transistor becomes substantially equal to a reference voltage; and a second control means that controls a gate voltage of the second transistor so that a drain voltage of the fourth transistor becomes substantially equal to the reference voltage.

In this high-voltage detecting circuit, the gate of the first transistor and the gate of the fourth transistor may be connected in common to each other, and the drain and gate of the third transistor, the gate of the fifth transistor, and the gate of the sixth transistor may be connected in common to each other.

In this high-voltage detecting circuit, the first control means may be a first differential amplifier supplied with the reference voltage and a drain voltage of the first transistor and having an output end connected to the gate of the first transistor, and the second control means may be a second differential amplifier supplied with the reference voltage and a drain voltage of the fourth transistor and having an output end connected to the gate of the second transistor.

The high-voltage detecting circuit may further comprise a comparing circuit that compares the reference voltage with a drain voltage of the sixth transistor.

In order to solve the above problems, according to still another embodiment of the present invention, a non-volatile semiconductor memory device is provided, which comprises a high-voltage regulator circuit including a charge pump circuit which operates under control by an output signal from the high-voltage detecting circuit and has an output end connected to a high-voltage terminal; and a memory cell array consisting of a plurality of memory cells for writing or deleting data thereon.

According to still another embodiment of the present invention, a voltage converting circuit is provided, which comprises a first transistor (T11) connected to a first node (CPD1) and to a second node (CPD2), a first capacitor (C11) connected between the first node (CPD1) and a third node (DCLK1); a second capacitor (C12) connected between the gate of the first transistor and a fourth node (GCLK1); a first buffer that drives the third node in response to a first control signal (DCLK10); and a second buffer that drives the third node in response to a second control signal (GCLK10). In the voltage converting circuit, the first buffer exerts a drive capacity at a voltage level change of the first control signal lower than a drive capacity at a voltage level change of the second control signal.

The first buffer may have a first inverter (IN34) and a second inverter (T38, T39), both inverters having their output ends connected in common to the third node. The first inverter may drive the third node in response to the first control signal and the second inverter may drive the third node in response to both first and second control signals.

The second inverter may have a second transistor (T38), and the gate of a third transistor may be driven by a result of logical operation of the first and second control signals.

The voltage converting circuit may further comprise a third transistor (T12) connected between the first node and the gate of the first transistor.

According to still another embodiment of the present invention, the voltage converting circuit is provided, which comprises a first transistor (T11) connect to the first node (CPD1) and to the second node (CPD2); a second transistor (T21) connect to the second node and to the third node (CPD3); a first capacitor (C11) connected between the first node and a fourth node (DCLK1); a second capacitor (C12) connected between the gate of the first transistor and a fifth node (GCLK1); a third capacitor (C21) connected between the second node and a sixth node (DCLK2); a fourth capacitor (C22) connected between the gate of the second transistor and a seventh node (GCLK2); a first buffer that drives the fourth node in response to a first control signal (DCLK10); a second buffer that drives the fifth node in response to a second control signal (GCLK10); a third buffer that drives the sixth node in response to a third control signal (DCLK10); and a fourth buffer that drives the seventh node in response to a fourth control signal (GCLK10). In the voltage converting circuit, the first buffer exerts a drive capacity at a voltage level change of the first control signal lower than a drive capacity at a voltage level change of the second control signal, and the third buffer exerts a drive capacity at a voltage level change of the third control signal lower than a drive capacity at a voltage level change of the fourth control signal.

The first buffer may have a first inverter (IN34) and a second inverter (T38, T39), both inverters having their output ends connected to the fourth node. The first inverter may drive the fourth node in response to the first control signal and the second inverter may drive the fourth node in response to the first, second, and fourth control signals. The third buffer may have a third inverter (IN54) and a fourth inverter (T58, T59), both inverters having their output ends connected to the sixth node. The third inverter may drive the sixth node in response to the third control signal and the fourth inverter may drive the sixth node in response to the third, fourth, and second control signals.

The second inverter may have a third transistor (T38) and a fourth transistor (T39), and the gate of the third transistor may be driven by a result of logical operation of the first and second control signals and the fourth transistor may be driven by a result of logical operation of the first and fourth control signals. The fourth inverter may have a fifth transistor (T58) and a sixth transistor (T59), and the gate of the fifth transistor may be driven by a result of logical operation of the third and fourth control signals and the sixth transistor may be driven by a result of logical operation of the third and second control signals.

The voltage converting circuit may further comprise a seventh transistor (T12) connected between the first node and the gate of the first transistor, and an eighth transistor (T22) connected between the second node and the gate of the second transistor.

A non-volatile semiconductor memory device according to one embodiment of the present invention comprises a memory cell to which data is written by supplying a high voltage generated by the voltage converting circuit to a word line.

A non-volatile semiconductor memory device according to another embodiment of the present invention comprises a memory cell to which data is written by supplying a high voltage generated by the voltage converting circuit to a well.

According to one aspect of the present invention, an exact replica of a current can be provided, and an accurate high-voltage detecting circuit and a high-voltage generating circuit can be provided.

According to another aspect of the present invention, a charge pump circuit can be provided, which suppresses flagging and rising of a drive signal and reduces a peak signal, and a semiconductor memory device can be provided, which has a voltage converting circuit functioning as such a charge pump circuit.

### BRIEF DESCRIPTION OF THE DRAWINGS

FIG. 1 is a functional block diagram of a non-volatile semiconductor memory device according to one embodiment of the present invention.

FIG. 2 is a functional block diagram of a high-voltage regulator circuit according to one embodiment of the present invention.

FIG. 3 is a functional block diagram of a high-voltage generating circuit according to one embodiment of the present invention.

FIG. 4 is a circuit diagram of a charge pump circuit according to one embodiment of the present invention.

FIG. 5 depicts the waveforms of signals for controlling a charge pump circuit according to one embodiment of the present invention.

FIG. 6 is a circuit diagram of a replica detecting circuit according to one embodiment of the present invention.

FIG. 7 is an explanatory diagram of an operation of a replica detecting circuit according to one embodiment of the present invention.

FIG. 8 is a circuit diagram of a conventional replica detecting circuit.

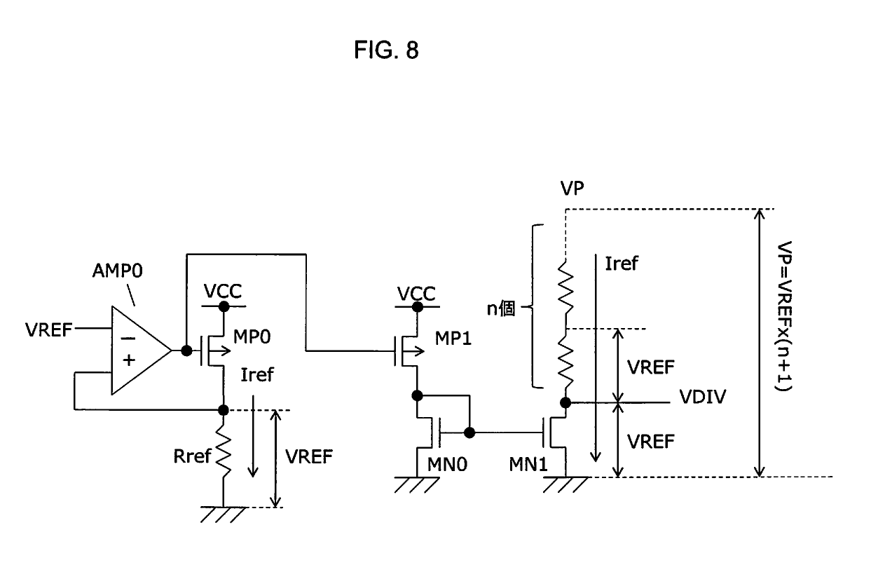

FIG. 9 is an explanatory diagram of an operation of the conventional replica detecting circuit.

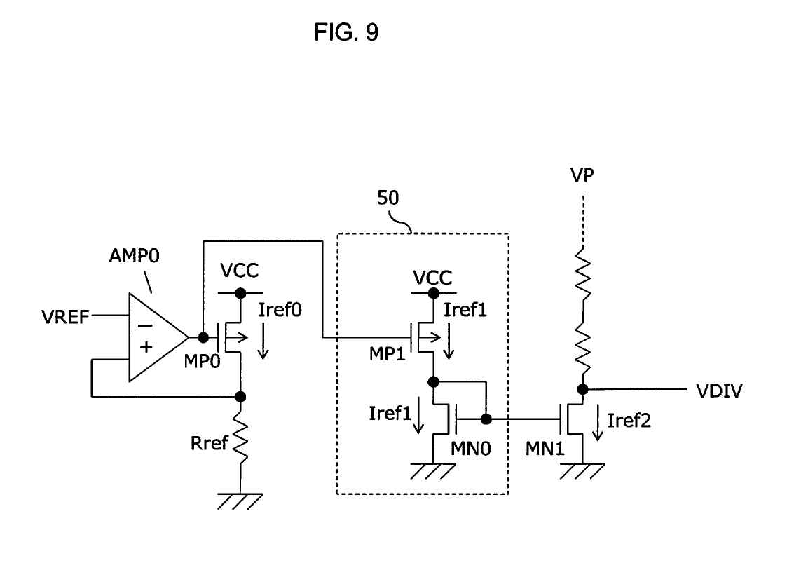

FIG. 10 is a circuit diagram of a clock buffer circuit according to one embodiment of the present invention.

FIG. 11 is a circuit diagram of a clock buffer circuit according to one embodiment of the present invention.

FIG. 12 is a waveform chart of voltages at nodes of a clock buffer circuit and a voltage converting circuit according to one embodiment of the present invention.

FIG. 13 is a waveform chart showing voltages at nodes of a clock buffer circuit according to one embodiment of the present invention and the sum ICC of currents of the clock buffer circuit.

FIG. 14 is a diagram of a conventional charge pump circuit and a waveform chart of drive signals for the charge pump circuit.

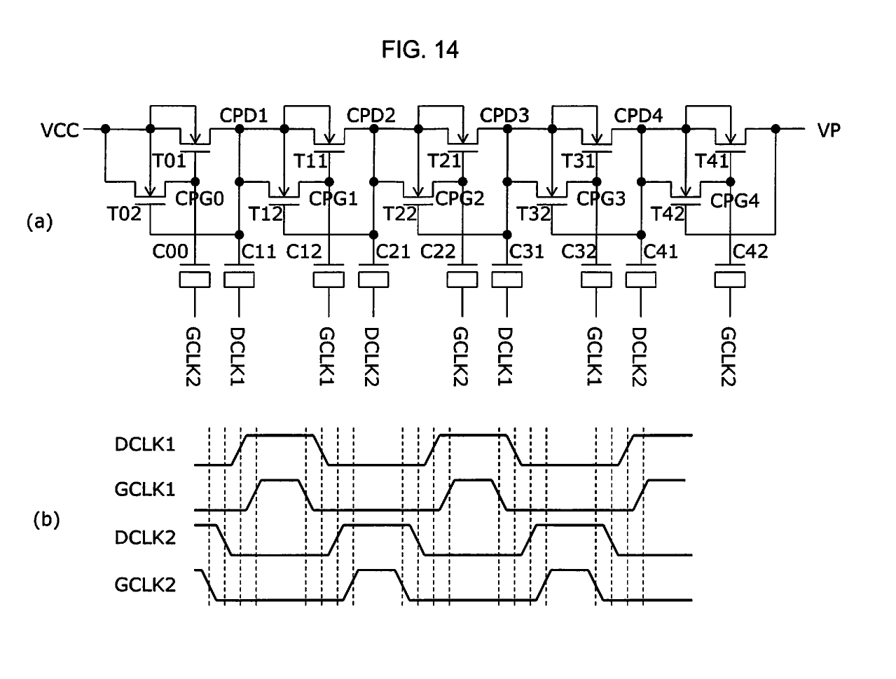

FIG. 15 is an example of a clock buffer circuit for driving the conventional charge pump circuit.

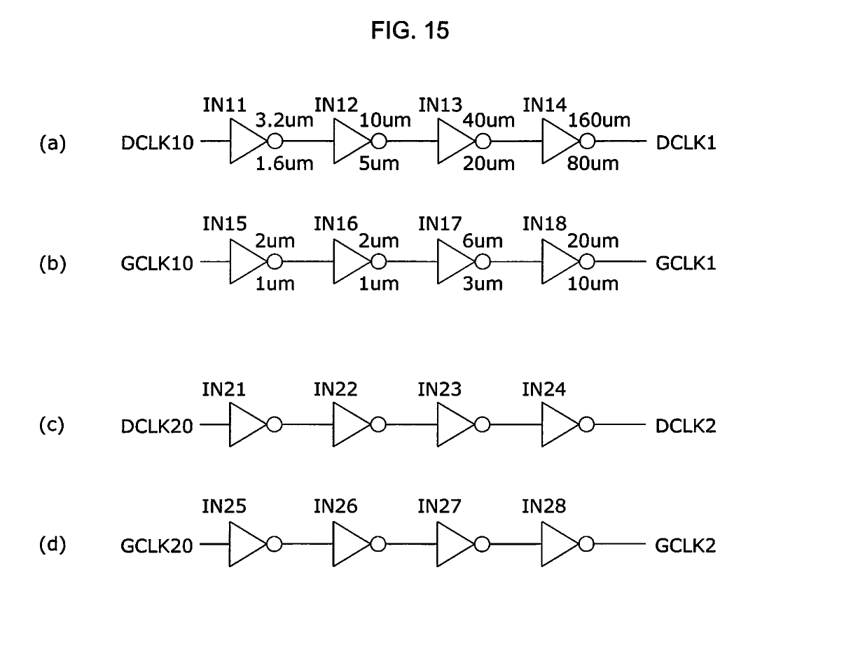

FIG. 16 is a waveform chart showing voltages at nodes of the clock buffer circuit for driving the conventional charge pump circuit and the sum ICC of currents of the clock buffer circuit.

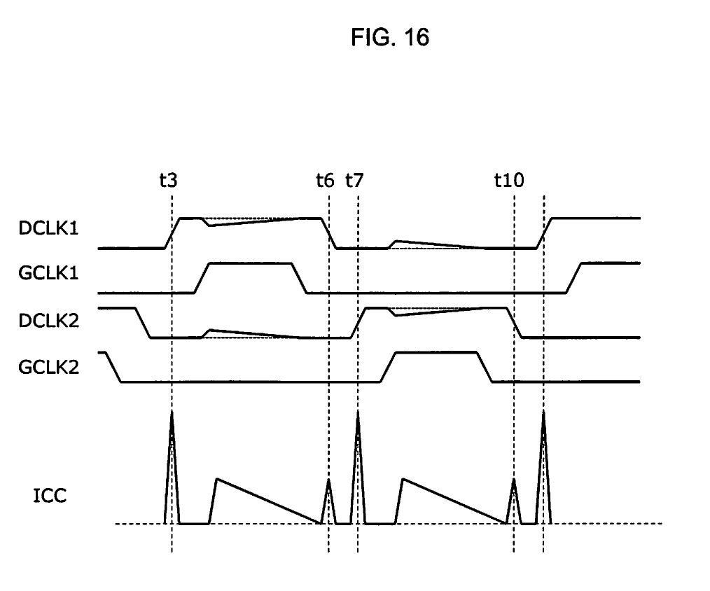

### DETAILED DESCRIPTION

Modes for carrying out the present inventions will now be described as embodiments. The present invention is not limited by the following embodiments to be described. The following embodiments may be modified into various forms and the invention may be carried out in those modified forms.

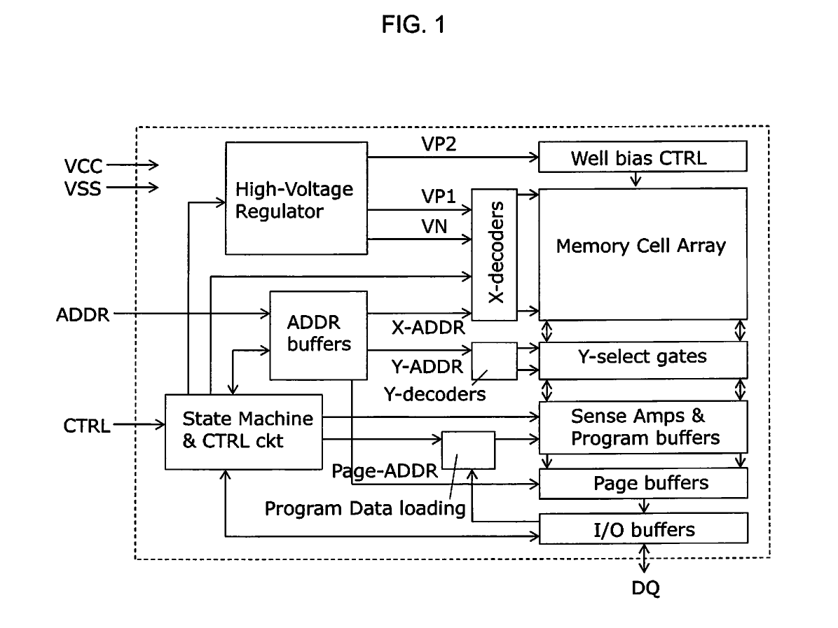

FIG. 1 is a block diagram of a non-volatile semiconductor memory device according to one embodiment of the present invention. This non-volatile semiconductor memory device may have a memory function only or may serve as a memory core used in combination with a CPU core, etc. The non-volatile semiconductor memory device operates with a single power supply that supplies a source voltage VCC (e.g., 1.8 V) and a ground voltage VSS. The non-volatile semiconductor memory is supplied with an address signal (ADDR), a control signal (CTRL), etc., and carries out data input/output through a DQ terminal. The address signal (ADDR) is supplied to an address buffer circuit (ADDR buffers), and a line address (X-ADDR) of the address signal (ADDR) is supplied to a line decoder (X-decoders) as a column address (Y-ADDR) of the address signal (ADDR) is supplied to a column decoder (Y-decoders). A memory cell array is composed of an array of PMOS transistors each having a charge accumulating layer (floating gate, nitrided film, etc.) and a control gate connected to each word line, which is driven by the line decoder (X-decoders). The PMOS transistors' sources are connected to a common source line and their drains are connected to bit lines, anyone of which is selected by a column selecting gate (Y-select gates) that is driven by the column decoder (Y-decoders). The column selecting gate (Y-select gates) is a multiplexer circuit. A voltage of a bit line selected by the multiplexer circuit (or a current flowing through the selected bit line) is sensed by a sensing amplifier (sense amps) as readout data, which is latched by a page buffer circuit (page buffers), and is transferred by a writing-in data loading circuit (program data loading) through an input/output buffer circuit (I/O buffer) in accordance with an address in a page buffer (Page-ADDR), to the DQ terminal.

Incoming writing-in data from the DQ terminal travels through the input/output buffer circuit (I/O buffer), and is latched by the page buffer circuit (page buffers), and then is held by a writing-in buffer circuit (program buffers). The data held by the writing-in buffer circuit is supplied to a bit line selected by the column selecting gate (Y-select gates), and is written to a selected memory cell. Data writing is carried out in such a way that zero voltage, a voltage equal to or higher than the source voltage VCC, a high voltage VP1, and a high voltage VP2 are supplied to the bit line, the common source line, the word line, and a well, respectively, to generate an inter-band tunnel current, thus trapping electrons in the charge accumulating layer. The high voltages VP1 and VP2 are, for example, 7 v and 5 V.

The above reading and writing operations are controlled by a state changing device (state machine) and a control circuit (CTRL ckt) that operate under control by the control signal (CTRL).

A high-voltage regulator circuit is controlled by the state changing device (state machine) and the control circuit (CTRL ckt), and outputs the high voltages VP1 and VP2 and a negative voltage VN. The high voltage VP1 and the negative voltage VN are supplied to the column decoder (X-decoders), while the high voltage VP2 is supplied to a well bias control circuit (well bias CTRL). As describe above, when data writing is carried out, zero voltage, a voltage equal to or higher than the source voltage VCC, the high voltage VP1, and the high voltage VP2 are supplied to the bit line, the common source line, the word line, and a well, respectively.

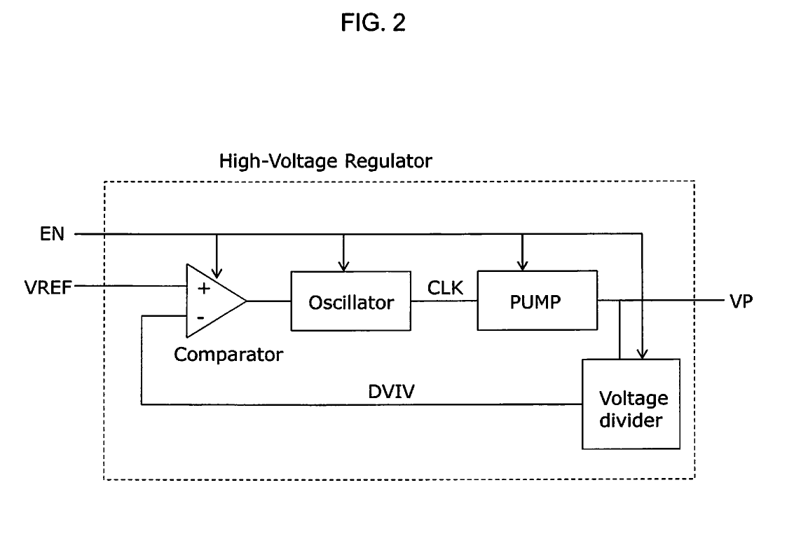

FIG. 2 is a part of a functional block diagram of a high-voltage regulator circuit (high-voltage regulator) according to one embodiment of the present invention. When outputting three voltages of VP1, VP2, and VN, the high-voltage regulator circuit is composed of three similar circuits (in which a negative voltage generating circuit is provided by reversing the positive/negative of a positive voltage generating circuit and of an output signal.)

The high-voltage regulator circuit (high-voltage regulator) includes a high-voltage generating circuit (PUMP), a voltage dividing circuit (voltage divider), a comparing circuit (comparator), and an oscillator.

The high-voltage generating circuit (PUMP), the voltage dividing circuit (voltage divider), the comparing circuit (comparator), and the oscillator are activated in accordance with a circuit activating signal (EN). The comparing circuit (comparator) compares a reference signal (VREF) supplied from a bandgap reference potential generating circuit (bandgap reference) with a feedback voltage DVIV output from the voltage dividing circuit (voltage divider) to control the operation of the oscillator. The oscillator supplies a clock signal (CLK) to the high-voltage generating circuit (PUMP). When an output voltage from the high-voltage generating circuit (PUMP) becomes excessively high, negative feedback works to suspend supply of the clock signal (CLK) from the oscillator. When an output voltage from the high-voltage generating circuit (PUMP) drops below a given voltage value, supply of the clock signal (CLK) is restarted.

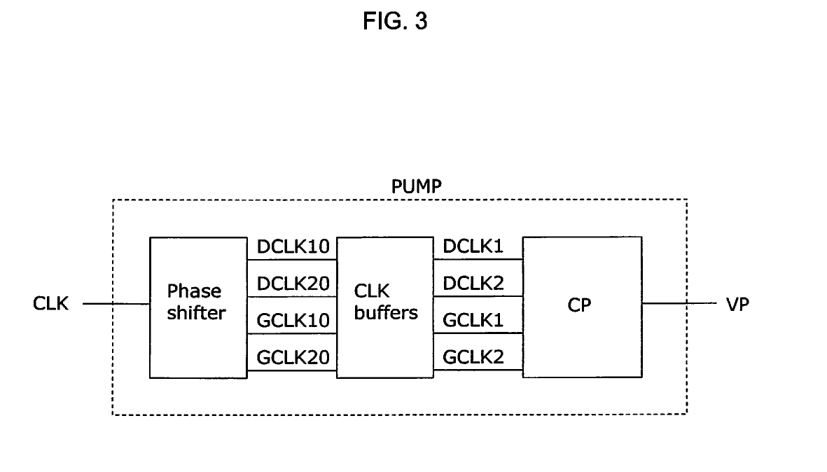

FIG. 3 is a functional block diagram of the high-voltage generating circuit (PUMP). The high-voltage generating circuit (PUMP) includes a phase shift circuit (phase shifter), a clock buffer circuit (CLK buffers), and a charge pump circuit (CP).

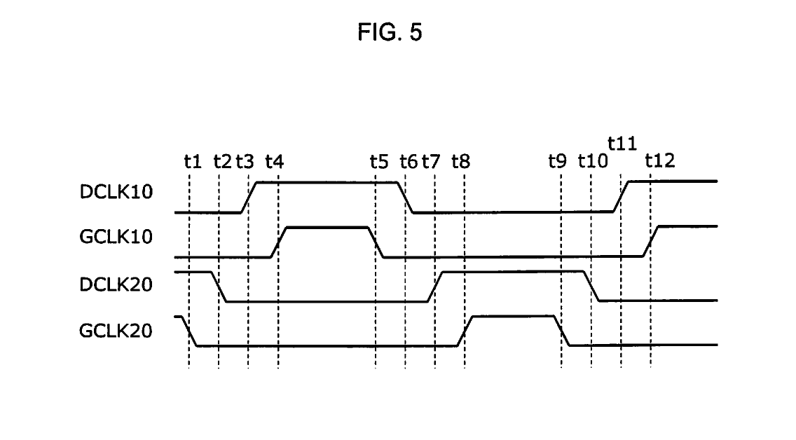

The clock signal (CLK) is supplied to the phase shift circuit (phase shifter), which generates four control signals DCLK10, GCLK 10, DCLK 20, and GCLK20 having four different phases, which will be described in detail later with reference to FIG. 5. The phase shift circuit (phase shifter) is composed of a plurality of delay circuits. The clock buffer circuit (CLK buffer) receives the control signals DCLK10, GCLK 10, DCLK 20, and GCLK20 and generates drive signals DCLK1, GCLK 1, DCLK 2, and GCLK2. The charge pump circuit (CP) receives drive signals DCLK1, GCLK 1, DCLK 2, and GCLK2 and generates a high voltage (such as the high voltages VP1, VP2 and the negative voltage VN.)

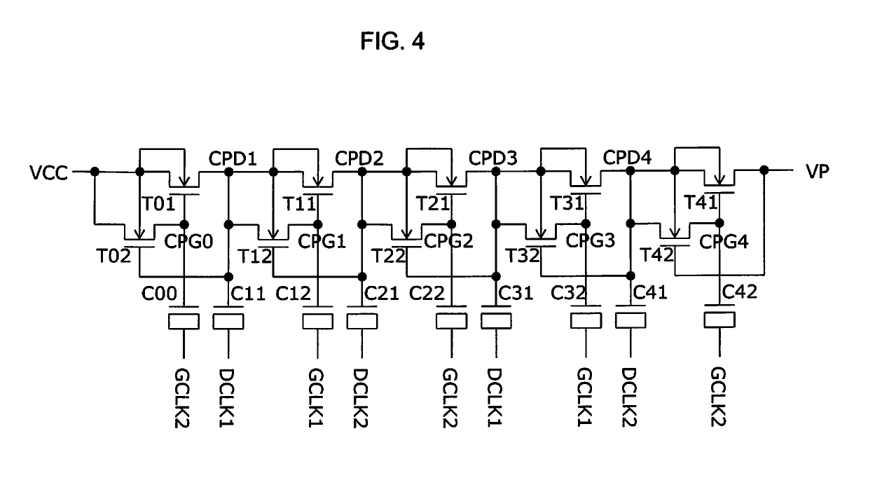

FIG. 4 is a circuit diagram of the charge pump circuit (CP). NMOS transistors T01, T11, T21, T31, and T41 are connected in series between a node supplied with the source voltage VCC and a node supplied with the raised voltage VP.

Each node between the transistors T01 and T11, between the transistors T11 and T21, between transistors the T21 and T31, and between the transistors the T31 and T41 is denoted as CPD1, CPD2, CPD3, and CPD4. Each node connected to the gate of each of the transistors T01, T11, T21, T31, and T41 is denoted as CPG0, CPG1, CPG2, CPG3, and CPG4.

Between the node of the source voltage VCC and the node CPG0, an NMOS transistor T02 is connected, whose gate is connected to the node CPD1. Between the node CPD1 and the node CPG1, an NMOS transistor T12 is connected, whose gate is connected to the node CPD2. Between the node CPD2 and the node CPG2, an NMOS transistor T22 is connected, whose gate is connected to the node CPD3. Between the node CPD3 and the node CPG3, an NMOS transistor T32 is connected, whose gate is connected to the node CPD4. Between the node CPD4 and the node CPG4, an NMOS transistor T42 is connected, whose gate is connected to the node of the raised voltage VP.

The node CPG0 is connected to a capacitor C00, whose opposed electrodes are driven by the drive signal GCLK2. The node CPG1 is connected to a capacitor C12, whose opposed electrodes are driven by the drive signal GCLK1. The node CPG2 is connected to a capacitor C22, whose opposed electrodes are driven by the drive signal GCLK2. The node CPG3 is connected to a capacitor C32, whose opposed electrodes are driven by the drive signal GCLK1. The node CPG4 is connected to a capacitor C42, whose opposed electrodes are driven by the drive signal GCLK2.

The node CPD1 is connected to a capacitor C11, whose opposed electrodes are driven by the drive signal DCLK1. The node CPD2 is connected to a capacitor C21, whose opposed electrodes are driven by the drive signal DCLK2. The node CPD3 is connected to a capacitor C31, whose opposed electrodes are driven by the drive signal DCLK1. The node CPD4 is connected to a capacitor C41, whose opposed electrodes are driven by the drive signal DCLK2.

FIG. 5 depicts the waveforms of the control signals DCLK10, GCLK10, DCLK20, and GCLK20 used for generating the drive signals DCLK1, GCLK1, DCLK2, and GCLK2.

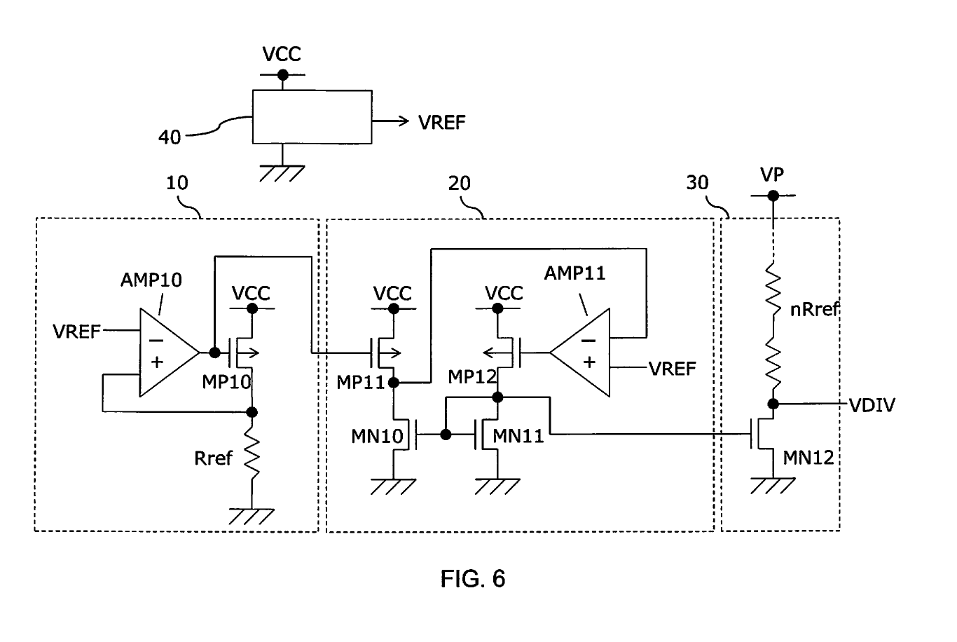

FIG. 6 is a circuit diagram of a replica detecting circuit according to one embodiment of the present invention. The replica detecting circuit is equivalent to the voltage dividing circuit (voltage divider) included in the high-voltage regulator circuit (high-voltage regulator) of FIG. 2. The replica detecting circuit includes a reference current generating circuit 10, an Iref converting circuit 20, a high-voltage shift circuit 30, and a reference voltage generating circuit 40. The reference voltage generating circuit 40 receives the source voltage VCC and the ground voltage VSS and generates a reference current VREF supplied to the reference current generating circuit 10 and to the Iref converting circuit 20. The reference voltage generating circuit 40 is composed of, for example, a bandgap circuit, etc., so as to be able to constantly generate the fixed reference voltage VREF regardless of the fluctuation of temperatures and the source voltage VCC.

The reference current generating circuit 10 is composed of a PMOS transistor MP10, a reference resistance Rref, and a differential amplifier AMP10. The PMOS transistor MP10 and the reference resistance Rref are connected in series between the node of the source voltage VCC and the node of the ground voltage VSS. The differential amplifier AMP10 has a negative input terminal supplied with the reference voltage VREF generated by the reference voltage generating circuit 40, and a positive input terminal connected to a connection point between the PMOS transistor MP10 and the reference resistance Rref, that is, the drain of the PMOS transistor MP10. The output end of the differential amplifier AMP10 is connected to the gate of the PMOS transistor MP10.

The Iref converting circuit 20 is composed of PMOS transistors MP11 and MP12, NMOS transistors MN10 and MN11, and a differential amplifier AMP11. The PMOS transistor MP11 and the NMOS transistor MN10 are connected in series between the node of the source voltage VCC and the node of the ground voltage VSS. The gate of the PMOS transistor MP11 is connected to the gate of the PMOS transistor MP10. The PMOS transistor MP11 and the PMOS transistor MP10 are the same size (gate length and gate width) with each other. The PMOS transistor MP12 and the NMOS transistor MN11 are connected in series between the node of the source voltage VCC and the node of the ground voltage VSS. The gate of the NMOS transistor MN11 is connected to its drain and to the gate of the NMOS transistor MN10. The NMOS transistor MN11 and the NMOS transistor MN10 are the same size (gate length and gate width) with each other. The differential amplifier AMP11 has a positive input terminal supplied with the reference voltage VREF generated by the reference voltage generating circuit 40, and a negative input terminal connected to a connection point between the PMOS transistor MP11 and the NMOS transistor MN10, that is, the drain of the PMOS transistor MP11. The output end of the differential amplifier AMP11 is connected to the gate of the PMOS transistor MP12.

The high-voltage shift circuit 30 is composed of a detecting resistance element (having a resistance value equivalent to that of n reference resistances Rref connected in series) and an NMOS transistor MN12. The detecting resistance element nRef and the NMOS transistor MN12 are connected in series between the high-voltage terminal VP and the node of the ground voltage VSS. The gate of the NMOS transistor MN12 is connected to the gate of the NMOS transistor MN11. The NMOS transistor MN11 and the NMOS transistor MN12 are same size (gate length and gate width) with each other. A detection terminal VDIV is lead out from a connection point between the detecting resistance element nRef and the NMOS transistor MN12.

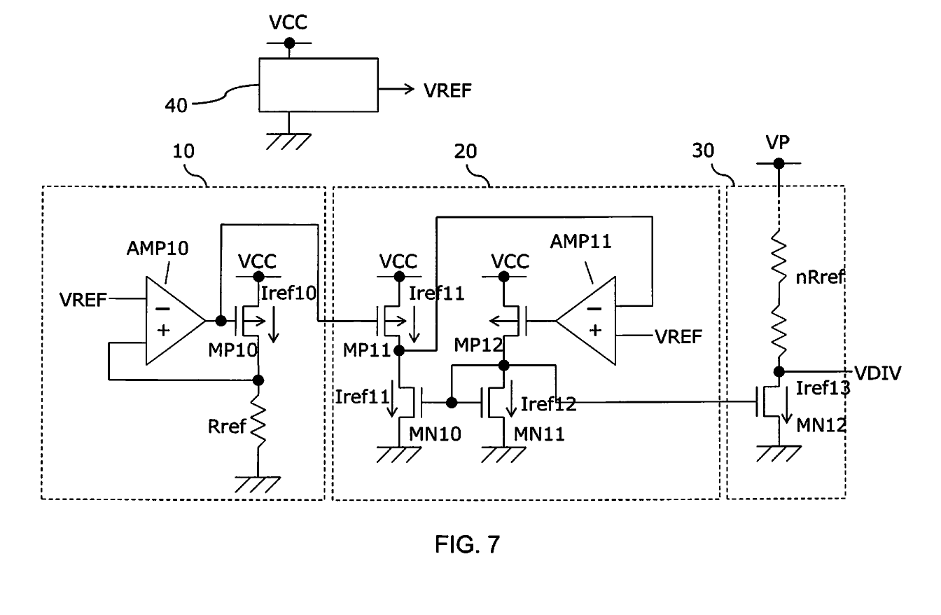

The operation of the replica detecting circuit shown in FIG. 6 will then be described referring to FIG. 7.

A reference current Iref10 flowing through a current path made up of the PMOS transistor MP10 and the reference resistance Rref is controlled through negative feedback by the differential amplifier AMP10 so that the relation VREF=Iref10×Rref is satisfied. Specifically, when a drain voltage of the PMOS transistor MP10 becomes lower than the reference voltage VREF, an output voltage from the differential amplifier AMP10 lowers, which causes the reference current Iref 10 to increase, thus raising the drain voltage of the PMOS transistor MP10. When the drain voltage of the PMOS transistor MP10 becomes higher than the reference voltage VREF, in contrast, an output voltage from the differential amplifier AMP10 rises, which causes the reference current Iref 10 to decrease, thus lowering the drain voltage of the PMOS transistor MP10. In this manner, the drain voltage of the PMOS transistor MP10 is kept equal to the reference voltage VREF. As a result, the reference current Iref10 flowing through the current path is so controlled that the relation VREF=Iref10×Rref is satisfied.

In the Iref converting circuit 20, the differential amplifier AMP11 carries out negative feedback control to keep a drain voltage of the PMOS transistor MP11 equal to the reference voltage VREF. Specifically, when the drain voltage of the PMOS transistor MP11 becomes lower than the reference voltage VREF, an output voltage from the differential amplifier AMP11 rises, which causes a current Iref 12 flowing through a current path made up of the PMOS transistor MP12 and the NMOS transistor MN11 to decrease and causes a current Iref 11 mirroring the current Iref 12 to decrease as well, thus raising the drain voltage of the PMOS transistor MP11. When the drain voltage of the PMOS transistor MP11 becomes higher than the reference voltage VREF, in contrast, an output voltage from the differential amplifier AMP11 lowers, which causes the current Iref 12 flowing through the current path made up of the PMOS transistor MP12 and the NMOS transistor MN11 to increase and causes the current Iref 11 mirroring the current Iref 12 to increase as well, thus lowering the drain voltage of the PMOS transistor MP11. In this manner, the drain voltage of the PMOS transistor MP11 is kept equal to the reference voltage VREF.

The PMOS transistor MP11 and the PMOS transistor MP10 have the gate common to each other and are the same size with each other. In addition, as describes above, the drain voltage of the PMOS transistor MP11 is the reference voltage VREF and the drain voltage of the PMOS transistor MP10 is also the reference voltage VREF. As a result, the current Iref 11 flowing through a current path made up of the PMOS transistor MP11 and the NMOS transistor MN10 becomes exactly the same in size as the reference current Iref 10.

The NMOS transistor MN12 and the NMOS transistors MN10 and MN11 have the gate common to each other and are the same size with each other. For this reason, a reference current Iref 13 flowing through a current path made up of the detecting resistance element nRef and the NMOS transistor MN12 becomes exactly the same in size as the reference current Iref 10 when a detection voltage VDIV matches the reference voltage VREF. Current replication is carried out in this manner. As a result, the detection voltage at the detection terminal VDIV becomes exactly the voltage given by the equation: VDIV=VP−n×Iref×Rref=VP−n×VREF. A variation ΔVP of the high voltage VP matches a variation ΔVDIV of the detection voltage VDIV. Hence extremely precise high voltage detection is achieved.

Turning to FIG. 2, the detection voltage VDVI from the replica detecting circuit equivalent to the high-voltage dividing circuit (voltage divider) in the high-voltage regulator circuit (high-voltage regulator) is supplied to the comparing circuit (comparator). The comparing circuit is composed of, for example, a differential amplifier, which compares the detection voltage VDVI with the reference voltage VREF to detect the high voltage VP. Specifically, when the high voltage VP is higher than a voltage VRFE×(1+n), the detection voltage VDVI is higher than the reference voltage VREF, which makes an output signal from the comparing circuit (comparator) inactive. When the high voltage VP is lower than the voltage VRFE×(1+n), the detection voltage VDVI is lower than the reference voltage VREF, which makes an output signal from the comparing circuit (comparator) active. In this manner, connecting the comparing circuit (comparator) to the replica detecting circuit equivalent to the high-voltage dividing circuit (voltage divider) provides a high-voltage detecting circuit.

Output from this high-voltage detecting circuit, i.e., output from the comparing circuit (comparator) is adjusted by controlling the operation of the oscillator. When the oscillator is active, it outputs an oscillating clock CLK, so that the high-voltage detecting circuit (PUMP) operates to raise the high voltage VP. When the oscillator is inactive, in contrast, the clock CLK stops oscillating, so that the high-voltage detecting circuit (PUMP) stops operating, thus lowering the high voltage VP. In this manner, the high voltage VP is kept under negative feedback control to maintain its voltage value REF×(1+n).

As described above, the replica detecting circuit of the present invention makes up the high-voltage detecting circuit, which is used in the high-voltage regulator circuit. This enables accurate control of high voltage.

As mentioned before, the memory cell array of FIG. 1 is a matrix array of PMOS transistors each having a charge accumulating layer (floating gate, nitrided film, etc.). Data writing to the memory cell array is carried out in such a way that a high voltage VP1 generated by the high-voltage regulator circuit (high-voltage regulator) is applied to the gate of the PMOS transistor, a high voltage VP2 generated by the same circuit is applied to a well, and the ground voltage VSS is applied to the drain of the PMOS transistor to generate an inter-band tunnel current, thereby trap charges in the charge accumulating layer. This data writing method requires an extremely accurate high-voltage control, for which the high-voltage detecting circuit is preferable.

While the above embodiment relates mainly to the high-voltage detecting circuit that detects a positive high voltage, a negative voltage detecting circuit that accurately detects a negative voltage can be provided by reversing the polarity of transistors of the replica detecting circuit.

The above embodiment has been described on the assumption that the PMOS transistors MP10 and MP11 have the same size and that the NMOS transistors MN10, MN11, and MN12 have the same size. However, the sizes, especially the gate widths, of the transistors may be made different from each other to vary the current drive capacities of the transistors. In such a case, the currents Iref10 and Iref13 maintain their proportional relation in correspondence to the proportional relation of the sizes of the transistors.

Another embodiment of the present invention will then be described.

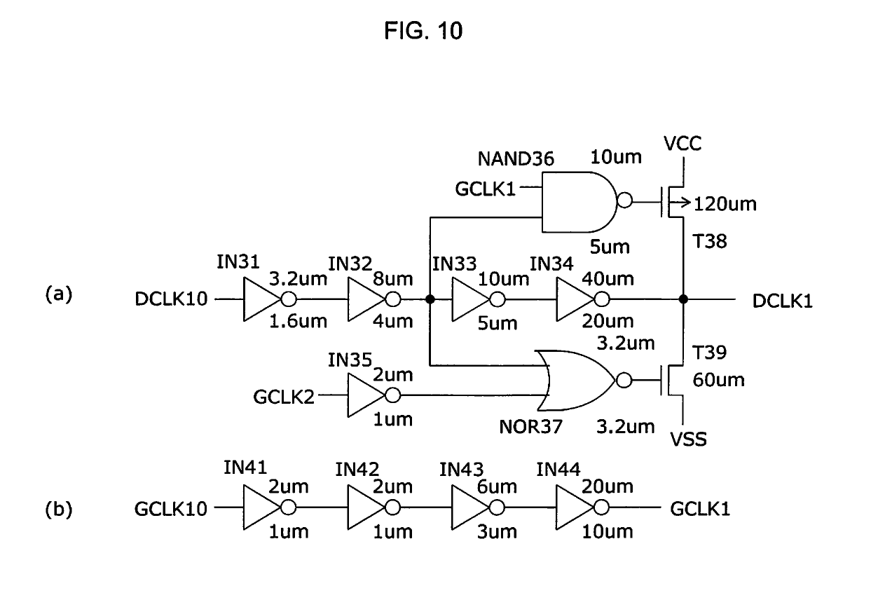

Each of FIGS. 10(a) and 10(b) depicts a part of the clock buffer circuit (CLK buffers). FIG. 10(a) depicts a circuit that generates the drive signal DCLK1 and FIG. 10(b) depicts a circuit that generates the drive signal GCLK1. The circuit that generates the drive signal DCLK1 includes a series circuit consisting of inverters IN31, IN32, IN33, and IN34 connected consecutively, a NAND gate (NAND36) supplied with an output signal from the inverter IN32 and the drive signal GCLK1, an inverter IN35 supplied with the drive signal GCLK2, a NOR gate (NOR37) supplied with an output signal from the inverter IN32 and an output signal from the inverter IN35, a PMOS transistor T38 driven by an output signal from the NAND36, and an NMOS transistor T39 driven by an output signal from the NOR37. The circuit that generates the drive signal GCLK1 includes inverters IN41, IN42, IN43, and IN44 connected consecutively. Numerical values in FIGS. 10(a) and 10(b) (e.g., 3.2 μm and 1.6 μm for the inverter IN31) represent the gate widths of PMOS transistors and NMOS transistors making up the inverters. (In the case of the inverter IN31, therefore, the gate width of the PMOS transistor is 3.2 μm and the same of the NMOS transistor is 1.6 μm.) The drive signal DCLK1 is driven by two inverters consisting of the inverter IN34 and an inverter circuit composed of the transistors T38 and T39. The gate widths of the transistors T38 and T39 are determined to be, for example, 120 μm and 60 μm, respectively, which are relatively large. (These gate widths are larger than the gate widths of transistors making up the inverter N34, but do not always have to be larger than the gate widths of transistors making up the inverter N34. Any gate width is allowed as long as it contributes to an increase in the total driving force.) This gate width setting effectively suppresses flagging and rising of the drive signal DCLK1.

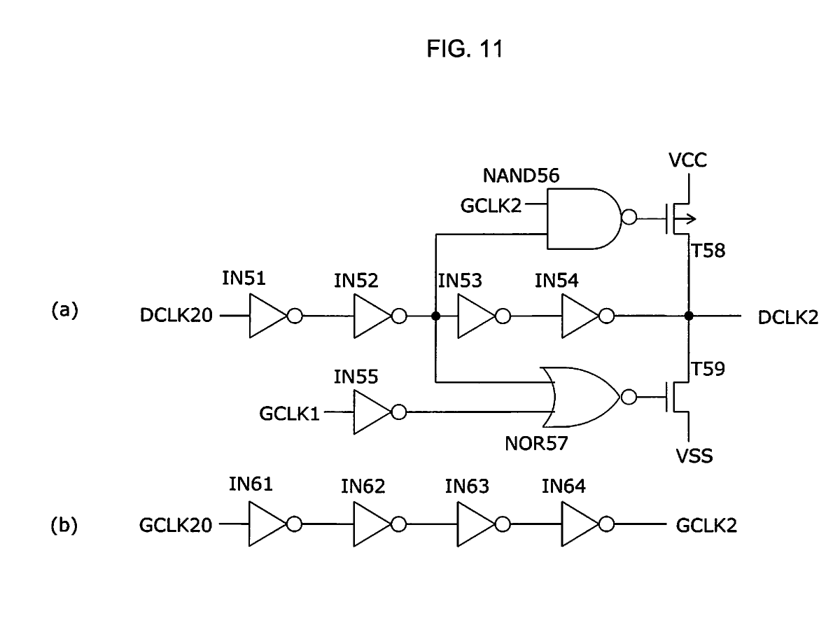

Each of FIGS. 11(a) and 11(b) depicts a part of the clock buffer circuit (CLK buffers). FIG. 11(a) depicts a circuit that generates the drive signal DCLK2, and FIG. 11(b) depicts a circuit that generates the drive signal GCLK2. The circuit that generates the drive signal DCLK2 includes a series circuit consisting of inverters IN51, IN52, IN53, and IN54 connected consecutively, a NAND gate (NAND56) supplied with an output signal from the inverter IN52 and the drive signal GCLK2, an inverter IN55 supplied with the drive signal GCLK1, a NOR gate (NOR57) supplied with an output signal from the inverter IN52 and an output signal from the inverter IN55, a PMOS transistor T58 driven by an output signal from the NAND56, and an NMOS transistor T59 driven by an output signal from the NOR57. The circuit that generates the drive signal GCLK2 includes inverters IN61, IN62, IN63, and IN64 connected consecutively. The drive signal DCLK2 is also driven by two inverters consisting of the inverter IN54 and an inverter circuit composed of the transistors T58 and T59. The gate widths of the transistors T58 and T59 are determined to be relatively large. This gate width setting effectively suppresses flagging or rising of the drive signal DCLK2.

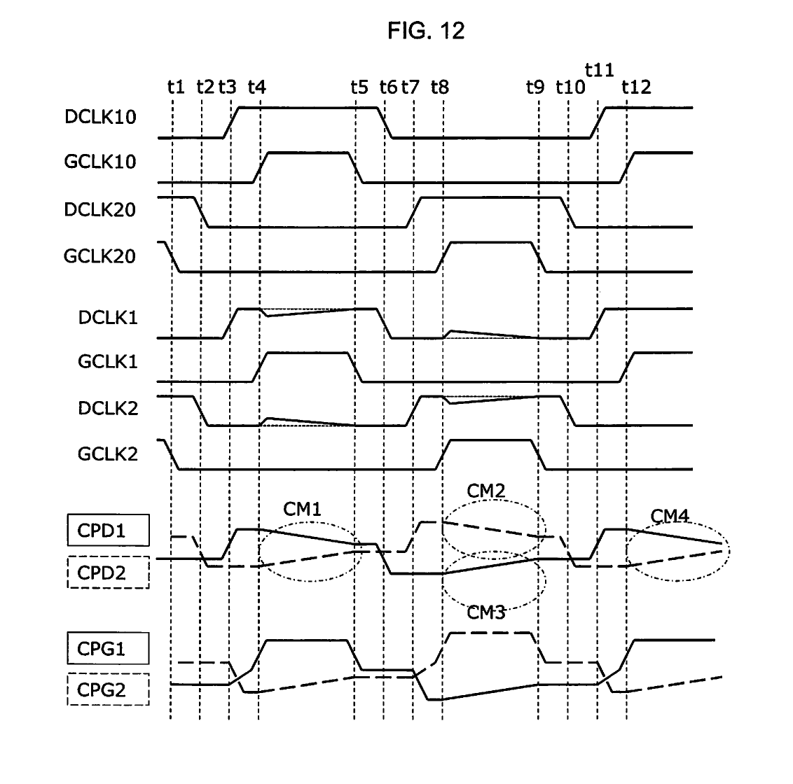

FIG. 12 is a waveform chart of voltages at nodes of the clock buffer circuit (CLK buffers) and the charge pump circuit (CP). FIG. 12 depicts the voltage waveforms of the control signals DCLK10, GCLK10, DCLK20, and GCLK20, the same of the drive signals DCLK1, GCLK1, DCLK2, and GCLK2, and the same at the nodes CPD1, CPD2 (indicated by a dotted line), CPG1, and CPG2 (indicated by a dotted line).

When the control signal GCLK20 goes low at a time t1, the drive signal GCLK2 goes low in response thereto. When the control signal DCLK20 goes low at a time t2, the drive signal DCLK2 goes low in response thereto.

When the control signal DCLK10 goes high at a time t3, the inverters IN31 to 34 response thereto, causing the drive signal DCLK1 to go high. As a result, a voltage at the node CPD1 is raised via the capacitor C11. At this point of time, the drive signal GCLK1 remains low, which keeps an output signal from the NAND36 high, thus leaving the transistor T38 non-conductive. In other words, the drive signal DCLK1 is driven only by the PMOS transistor (with a gate width of 40 μm) of the inverter IN34. An instantaneous current generated at a voltage rise at the node CPD1, therefore, is not so large, which will be described later.

When the control signal GCLK10 goes high at a time t4, the inverters IN41 to 44 response thereto, causing the drive signal GCLK1 to go high. As a result, a voltage at the node CPG1 is raised via the capacitor C12, which turns the transistor T11 conductive, so that a raised voltage at the node CPD1 is transferred to the node CPD2. This charge migration (CM1) gradually lowers the voltage at the node CPD1 while gradually raising the voltage at the node CPD2. At this point of time, the drive signal GCLK1 is high, which makes an output signal from the NAND36 low, turning the transistor T38 conductive. In other words, the drive signal DCLK1 is driven at a high voltage level by the PMOS transistor (with a gate width of 40 μm) of the inverter IN34 and by the transistor T38 (with a gate width of 120 μm). Hence the flagging of the drive signal DCLK1 turns out to be insignificant, as shown in FIG. 12, which indicates that the flagging is suppressed effectively. Meanwhile, at the same point of time, the drive signal DCLK2 is driven at a low voltage level by the inverter IN54 (with the transistor's gate width of 20 μm) and by the transistor T59 (with a gate width of 60 μm). The rising of the drive signal DCLK2 turns out to be insignificant, as shown in FIG. 12, which indicates that the rising is suppressed effectively.

When the control signal GCLK10 goes low at a time t5, the inverters IN41 to 44 response thereto, causing the drive signal GCLK1 to go low. As a result, the transistor T11 becomes non-conductive, which leads to the end of transfer of the raised voltage at the node CPD1 to the node CPD2.

When the control signal DCLK10 goes low at a time t6, the inverters IN31 to 34 response thereto, causing the drive signal DCLK1 to go low. At this point of time, the drive signal GCLK2 remains low, which keeps an output signal from the NOR37 low, thus leaving the transistor T39 non-conductive. As a result, the drive signal DCLK1 is driven only by the NMOS transistor (with a gate width of 20 μm) of the inverter IN34. An instantaneous current flowing through the clock buffer circuit, therefore, is not so large, which will be described later.

When the control signal DCLK20 goes high at a time t7, the inverters IN51 to 54 response thereto, causing the drive signal DCLK2 to go high. As a result, a voltage at the node CPD2 is raised via the capacitor C21. At this point of time, the drive signal GCLK2 remains low, which keeps an output signal from the NAND56 high, thus leaving the transistor T58 non-conductive. In other words, the drive signal DCLK2 is driven only by the PMOS transistor (with a gate width of 40 μm) of the inverter IN54. An instantaneous current generated at a voltage rise at the node CPD2, therefore, is not so large, which will be described later.

When the control signal GCLK20 goes high at a time t8, the inverters IN61 to 64 response thereto, causing the drive signal GCLK2 to go high. As a result, a voltage at the node CPG2 is raised via the capacitor C22, which turns the transistor T21 conductive, so that a raised voltage at the node CPD2 is transferred to the node CPD3. This charge migration (CM2) gradually lowers the voltage at the node CPD2 while gradually raising the voltage at the node CPD3 (which is not depicted). At this point of time, the drive signal GCLK2 is high, which makes an output signal from the NAND56 low, turning the transistor T58 conductive. In other words, the drive signal DCLK2 is driven at a high voltage level by the PMOS transistor (with a gate width of 40 μm) of the inverter IN54 and by the transistor T58 (with a gate width of 120 μm). Hence the flagging of the drive signal DCLK2 turns out to be insignificant, as shown in FIG. 12, which indicates that the flagging is suppressed effectively. Meanwhile, at the same point of time, the drive signal DCLK1 is driven at a low voltage level by the inverter IN34 (with the transistor's gate width of 20 μm) and by the transistor T39 (with a gate width of 60 μm). The rising of the drive signal DCLK1 turns out to be insignificant, as shown in FIG. 12, which indicates that the rising is suppressed effectively.

At the time t8, the drive signal GDLK2 turning into a high-level signal leads to a voltage rise at the node CPG0 via the capacitor C00. As a result, the transistor T01 becomes conductive, so that charges are transferred sequentially from the node of the source voltage VCC to the node CPD1. This charge migration (CM3) gradually raises a voltage at the node CPD1.

When the control signal GCLK20 goes low at a time t9, the inverters IN61 to 64 response thereto, causing the drive signal GCLK2 to go low. As a result, the transistor T21 becomes non-conductive, which leads to the end of transfer of the raised voltage at the node CPD2 to the node CPD3.

When the control signal DCLK20 goes low at a time t9, the inverters IN51 to 54 response thereto, causing the drive signal DCLK2 to go low. At this point of time, the drive signal GCLK1 remains low, which keeps an output signal from the NOR57 low, thus leaving the transistor T59 non-conductive. As a result, the drive signal DCLK2 is driven only by the NMOS transistor (with a gate width of 20 μm) of the inverter IN54. An instantaneous current flowing through the clock buffer circuit, therefore, is not so large, which will be described later.

When the control signal DCLK10 goes high at a time t11, the same operation as the operation at the time t3 is carried out. When the control signal GCLK10 goes high at a time t12, the same operation as the operation at the time t4 is carried out, in which operation charge migration occurs (CM4).

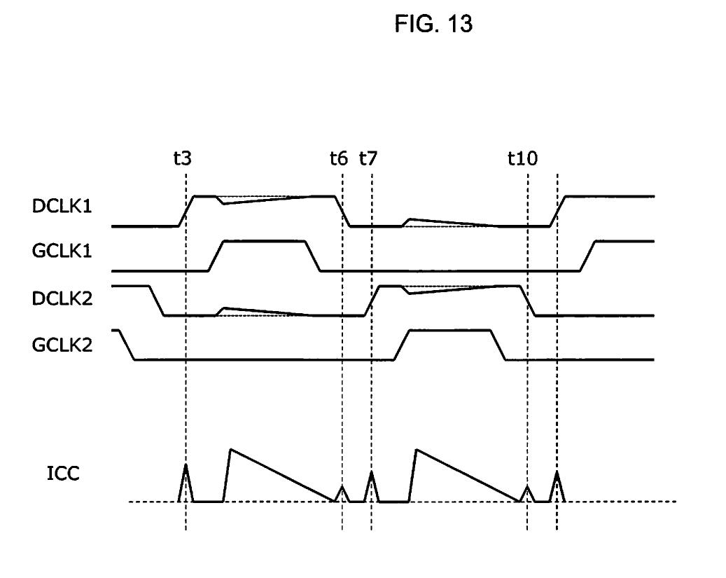

FIG. 13 is a waveform chart showing voltages at nodes of the clock buffer circuit and the sum ICC of currents of the clock buffer circuit. The current sum ICC represents the sum of currents flowing from the node of the source voltage VCC toward the node of the ground voltage VSS. At the time t3 at which the drive signal DCLK1 in its low-level state changes into a high-level state, the pull-up drive capacity of the clock buffer circuit that generates the drive signal DCLK1 is not so large. As a result, an inflow of a large instantaneous current to the clock buffer circuit is prevented effectively. Likewise, when the drive signal DCLK2 in its low-level state changes into a high-level state (t7), an inflow of a large instantaneous current to the clock buffer circuit is prevented effectively.

The pull-down drive capacity of the clock buffer circuit that generates the drive signal DCLK1 is not so large when the drive signal DCLK1 in its high-level state changes into a low-level state (t6). At this time, therefore, an inflow of a large instantaneous current to the clock buffer circuit is prevented effectively. Likewise, when the drive signal DCLK2 in its high-level state changes into a low-level state (t10), an inflow of a large instantaneous current to the clock buffer circuit is prevented effectively.

In this manner, a local drop in the source voltage can be avoided by dispersing peak currents. This prevents the arising of a problem that a large current change di/dt acting as an inductor element creates a noise source.

### EXPLANATIONS OF LETTERS OR NUMERALS

10 Reference current generating circuit
20 Iref converting circuit
30 High-voltage shift circuit
40 Reference voltage generating circuit
T3, t6, t7, t10 time
DCLK1, GCLK1, DCLK2, GCLK2 drive signal
ICC Sum of currents flowing through the clock buffer circuit

What is claimed is:

1. A replica circuit comprising:
a first conductivity type first transistor;
a first current path including a first conductivity type second transistor and a second conductivity type third transistor that are connected in series with each other;
a second current path including a first conductivity type fourth transistor so configured that a current equivalent to a current flowing through the first transistor flows through the first conductivity type fourth transistor and a second conductivity type fifth transistor so configured that a current equivalent to a current flowing through the third transistor flows through the second conductivity type fifth transistor, the first conductivity type fourth transistor and the second conductivity type fifth transistor being connected in series with each other;
a second conductivity type sixth transistor so configured that a current equivalent to a current flowing through the third transistor flows through the second conductivity type sixth transistor;
a first control means which controls a gate voltage of the first transistor so that a drain voltage of the first transistor becomes substantially equal to a reference voltage; and
a second control means that controls a gate voltage of the second transistor so that a drain voltage of the fourth transistor becomes substantially equal to the reference voltage.

2. The replica circuit according to claim 1, wherein
a gate of the first transistor and a gate of the fourth transistor are connected in common to each other, and wherein
a drain and a gate of the third transistor, a gate of the fifth transistor, and a gate of the sixth transistor are connected in common to each other.

3. The replica circuit according to claim 1, wherein
the first control means is a first differential amplifier supplied with the reference voltage and a drain voltage of the first transistor and having an output end connected to a gate of the first transistor, and the second control means is a second differential amplifier supplied with the reference voltage and a drain voltage of the fourth transistor and having an output end connected to a gate of the second transistor.

4. A high-voltage detecting circuit comprising:
a first resistance;
a second resistance
a high-voltage terminal; a reference voltage terminal; and
a replica circuit comprising:
a first conductivity type first transistor;
a first current path including a first conductivity type second transistor and a second conductivity type third transistor that are connected in series with each other;
a second current path including a first conductivity type fourth transistor so configured that a current equivalent to a current flowing through the first transistor flows through the first conductivity type fourth transistor and a second conductivity type fifth transistor so configured that a current equivalent to a current flowing through the third transistor flows through the second conductivity type fifth transistor, the first conductivity type fourth transistor and the second conductivity type fifth transistor being connected in series with each other;
a second conductivity type sixth transistor so configured that a current equivalent to a current flowing through the third transistor flows through the second conductivity type sixth transistor;
a first control means which controls a gate voltage of the first transistor so that a drain voltage of the first transistor becomes substantially equal to a reference voltage; and
a second control means that controls a gate voltage of the second transistor so that a drain voltage of the fourth transistor becomes substantially equal to the reference voltage,
wherein the first conductivity type first transistor is connected in series with the first resistance to make up a reference current path, and
wherein the second conductivity type sixth transistor is connected in series with the second resistance between the high-voltage terminal and the reference voltage terminal to make a third current path.

5. The high-voltage detecting circuit according to claim 4, wherein:
the gate of the first transistor and the gate of the fourth transistor are connected in common to each other; and
the drain and the gate of the third transistor, a gate of the fifth transistor, and the gate of the sixth transistor are connected in common to each other.

6. The high-voltage detecting circuit according to claim 4, wherein the first control means is a first differential amplifier supplied with the reference voltage and the drain voltage of the first transistor and having an output end connected to the gate of the first transistor, and the second control means is a second differential amplifier supplied with the reference voltage and the drain voltage of the fourth transistor and having an output end connected to the gate of the second transistor.

7. The high-voltage detecting circuit according to claim 4, further comprising a comparing circuit which compares the reference voltage with the drain voltage of the sixth transistor.

8. A high-voltage regulator circuit comprising a charge pump that operates under control by an output signal from the high-voltage detecting circuit of claim 4, the charge pump having an output end connected to the high-voltage terminal.

9. A non-volatile semiconductor memory device comprising a memory cell array including a plurality of memory cells for writing or deleting data thereon by an output voltage from the high-voltage regulator circuit of claim 8.

10. A voltage converting circuit comprising:
a first transistor connected to a first node and to a second node;
a first capacitor connected between the first node and a third node;
a second capacitor connected between a gate of the first transistor and a fourth node;
a first buffer which drives the third node in response to a first control signal; and
a second buffer which drives the third node in response to a second control signal,
wherein the first buffer exerts a drive capacity at a voltage level change of the first control signal lower than a drive capacity at a voltage level change of the second control signal.

11. The voltage converting circuit according to claim 10, wherein:
the first buffer includes a first inverter and a second inverter, both inverters having their output ends connected in common to the third node; and
the first inverter drives the third node in response to the first control signal and the second inverter drives the third node in response to both first and second control signals.

12. The voltage converting circuit according to claim 11, wherein:
the second inverter has a second transistor; and
a gate of the second transistor is driven by a result of logical operation of the first and second control signals.

13. The voltage converting circuit according to claim 10, further comprising a third transistor connected between the first node and a gate of the first transistor.

14. The voltage converting circuit according to claim 10, comprising:
a second transistor connected to the second node and to the third node;
a third capacitor connected between the second node and a sixth node;
a fourth capacitor connected between a gate of the second transistor and a seventh node;
a third buffer which drives the sixth node in response to a third control signal; and
a fourth buffer which drives the seventh node in response to a fourth control signal,
wherein a drive capacity of the third buffer at a voltage level change of the third control signal is lower than a drive capacity of the third buffer at a voltage level change of the fourth control signal.

15. The voltage converting circuit according to claim 14, wherein:
the first buffer includes a first inverter and a second inverter, both inverters having their output ends connected to the fourth node;
the first inverter drives the fourth node in response to the first control signal and the second inverter drives the fourth node in response to the first, second, and fourth control signals;
the third buffer includes a third inverter and a fourth inverter, the both inverters having their output ends connected to the sixth node; and
the third inverter drives the sixth node in response to the third control signal and the fourth inverter drives the sixth node in response to the third, fourth, and second control signals.

16. The voltage converting circuit according to claim 15, wherein:
the second inverter includes a third transistor and a fourth transistor;
a gate of the third transistor is driven by a result of logical operation of the first and second control signals and the fourth transistor is driven by a result of logical operation of the first and fourth control signals, wherein
the fourth inverter includes a fifth transistor (T58) and a sixth transistor; and
a gate of the fifth transistor is driven by a result of logical operation of the third and fourth control signals and the sixth transistor is driven by a result of logical operation of the third and second control signals.

17. The voltage converting circuit according to claim 14, further comprising:
a seventh transistor connected between the first node and a gate of the first transistor; and
an eighth transistor connected between the second node and a gate of the second transistor.

18. A non-volatile semiconductor memory device comprising:
a voltage converting circuit comprising:
a first transistor connected to a first node and to a second node;
a first capacitor connected between the first node and a third node;
a second capacitor connected between a gate of the first transistor and a fourth node;
a first buffer which drives the third node in response to a first control signal; and
a second buffer which drives the third node in response to a second control signal,
wherein the first buffer exerts a drive capacity at a voltage level change of the first control signal lower than a drive capacity at a voltage level change of the second control signal; and
a memory cell to which data is written by supplying a high voltage generated by the voltage converting circuit to a word line.

19. A non-volatile semiconductor memory device comprising:
a voltage converting circuit comprising:
a first transistor connected to a first node and to a second node;
a first capacitor connected between the first node and a third node;
a second capacitor connected between a gate of the first transistor and a fourth node;
a first buffer which drives the third node in response to a first control signal; and
a second buffer which drives the third node in response to a second control signal,
wherein the first buffer exerts a drive capacity at a voltage level change of the first control signal lower than a drive capacity at a voltage level change of the second control signal; and
a memory cell to which data is written by supplying a high voltage generated by the voltage converting circuit to a well.
